(19) United States
(12) Patent Application Publication
(10) Pub. No.: US 2007/0262808 A1
(43) Pub. Date: Nov. 15, 2007

(54) Integrated Speedup Circuit

(76) Inventor: Riccardo Lavorerio, Muenchen (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/383,392

(22) Filed: May 15, 2006

(51) Int. Cl. H03K 17/16

(52) U.S. Cl. 327/390

(57) ABSTRACT

A speedup circuit includes a control current source, a current limiter, and a driver for driving a target signal related to a reference signal. The control current source is controllable according to the reference signal and the current limiter receives a feedback signal from the driver.

### TECHNICAL FIELD

The present invention generally relates to the field of integrated circuits within electronic devices and more specifically to speedup circuits.

### BACKGROUND

Within integrated systems there are a plurality of different modules which need a predefined operation condition. For instance it has to be ensured that a certain module will receive always a certain input current or voltage for proper operation. The integrated circuits which are part of the systems are forming large and different capacitances that are to be charged or discharged, respectively to achieve the above-mentioned predefined conditions. The currents inside of these integrated circuits are generally small which means that these small currents require long periods of time to charge the corresponding capacitors.

For example, a usual current mirror may be used for biasing identical output currents for more than one operational amplifier. Due to the plurality of connected output legs the charging capacity will increase and the charging process will take a lot of time rendering the whole system slow. This effect may be a disadvantage within memory systems, for instance, where all integrated modules have to work in a very fast way.

Therefore, there is a need to provide speedup circuits which are adapted to supply an additional current and/or voltage for speeding up achieving of predefined operation conditions or the like.

### SUMMARY

A circuit may include a current source generating an output signal, a current limiter, and a driver for driving a target signal related to a reference signal. Further, the current source can be controllable according to the reference signal and the current limiter can be adapted to receive a feedback signal from the driver.

Furthermore, a method for speeding up achieving a target signal related to a reference signal comprises: generating a control current on the basis of the reference signal, driving an achieving of the target signal and limiting the control current on the basis of the driving step.

### BRIEF DESCRIPTION OF THE DRAWINGS

The accompanying drawings are included to provide a further understanding of the invention, and are incorporated in and constitute a part of this specification. The drawings illustrate embodiments of the present invention and together with the description serve to explain the principles of the invention. In the drawings,

FIG. 1 is a conventional bootstrap circuit;

FIG. 2 shows one embodiment of the present invention within a System;

FIG. 3 is a detailed view of one embodiment of the present invention connected to a current mirror bank; and

FIG. 4 shows one embodiment of the present invention according to a low power implementation.

Reference will be made in detail to the embodiments of the invention examples, which are illustrated in the accompanying drawings. The following description relates to various embodiments based on which one skilled in the art will understand the invention. Nevertheless, one skilled in the art will appreciate that the invention is likewise applicable to further embodiments, which are covered by the scope of the accompanying claims.

### DETAILED DESCRIPTION

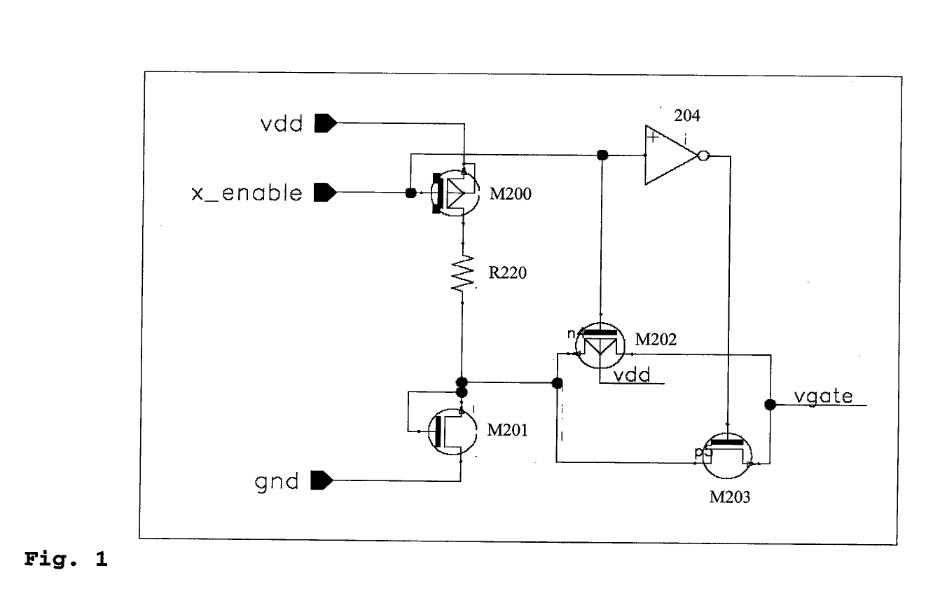

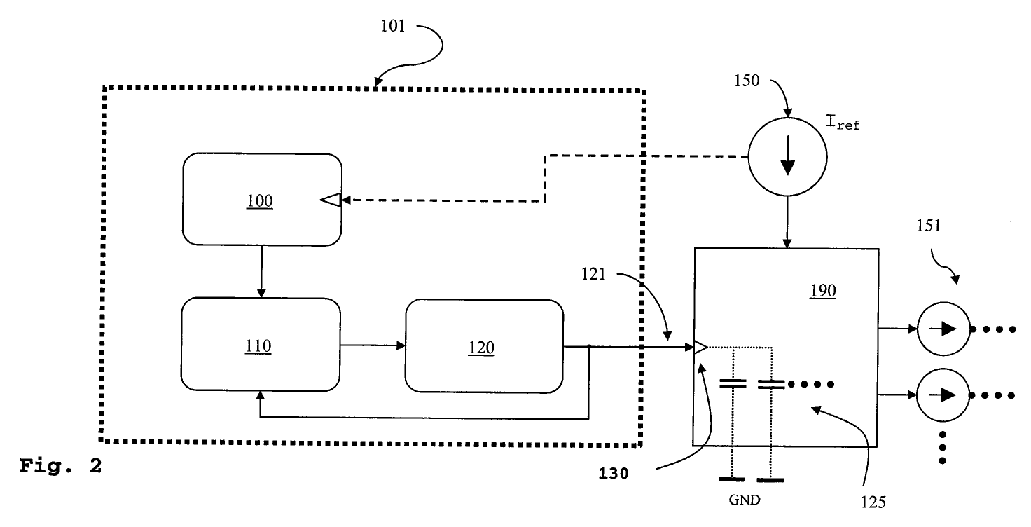

With reference to FIG. 1, a schematic of a conventional speedup or bootstrap circuit is shown. The bootstrap circuit is adapted to receive an enable signal x_enable which is used to control the gate of transistor M200. According to this embodiment node 130 is charged with a current defined by means of resistor R220 and transistor M201 which is coupled as a diode. Node 130 can be connected to an external circuit and the current generated by the speedup circuit at node 130 may be used for supporting charging of the input capacitance of a current mirror bank for instance. This is schematically shown with reference to FIG. 2 with capacitance 125.

The inverter 204 corresponds to a conventional inverter circuitry including for instance two transistors. A person skilled in the art would appreciate that the inverter could be implemented in different ways. The objective of the inverter circuitry 204 is to invert the input signal under defined timing constraints.

The output current at node 130 is uncorrelated with the reference current which is the current to be achieved within the external circuit. For instance, in case of the above mentioned current mirror 190, the reference current corresponds to the current which is to be biased or mirrored, respectively via the current mirror. Additionally, this speedup circuit needs an enable signal or circuit that is provided by transistor M200. In general, the node 130 output is affected by the resistance R220 and the threshold voltage Vth of the diode. However, the bootstrap circuit receives no feedback signal from the external circuit or node which is to be supported and an additional enable signal can be necessary.

FIG. 2 shows, for example, one embodiment wherein a speedup circuit 101 is used to improve the timing behavior of a current mirror bank 190. Current mirror bank 190 is schematically shown and receives two signals, the output signal of the speedup circuit 101 and in addition to this a reference current 150. The reference current is the current which is to be transferred or biased, respectively by means of the current mirror bank. A person skilled in the art would appreciate that other arrangements performing the functionality of a current mirror may be used in connection with some embodiments of the invention.

The output signals 151 of the current mirror 190 correspond to the biased currents. According to one embodiment, a single reference current 150 is replicated by means of current mirror 190 into a diversity of target currents or bias currents 151 which may be used for operating different modules or circuitries. Herein the reference current 150 is schematically illustrated by means of a current generator 151. According to some embodiments of the invention the current 151 may be generated by a transistor circuitry.

According to some embodiments, current mirror 190 receives the output signal 121 of speedup circuit 101. The output signal 121 can be used to drive the charging of the input capacitance of current mirror 190. With reference to FIG. 2, input capacitance 125 may be measured against the ground potential GND. The more biased currents 151 are desired for operating further modules the more the rate of the input capacitance of the mirror 190 will increase. Due to increasing of the capacitance the timing behavior of the mirror is influenced and the time until the bias currents 151 achieve their desired value increases as well.

The speedup circuit 101 may comprise three modules: a control current source 100, a current limiter 110 and a driver 120. Current limiter 110 is adapted to receive at a control input the control current. At a feedback input it receives a feedback signal corresponding to the output signal of the driver 120. According to one embodiment, the feedback signal, for example, may correspond to the signal which is used to drive one of the current mirror arrangements 190.

Control current source 100 is controllable according to the reference current which is feed to current mirror 190. According to one embodiment, the control current source 100 will generate a control current equal to the reference current 150 of the corresponding current source. In one embodiment, a predetermined ratio between the reference current 150 and the source 100 is set. Thus, the current limiter 110 has to be reconfigured to deal with the new current value. The new current value may be associated with the predetermined ratio.

In one embodiment, the current source can be implemented by means of a voltage source or the like, but the main functionality of the source 100 is to provide a current for operating and/or controlling the speedup circuit 101.

By means of the feedback signal, the current limiter can be controlled in a predetermined manner. For instance, according to one implementation, if the feedback signal reaches a threshold, the current limiter 110 may cause that the driver 120 will be switched off. In one embodiment, the output signal of the current limiter 110, which is in turn the input signal of the driver 120, turns off the driver.

Subsequently, the current mirror 190 operates according to the desired conditions and the output currents or signals 151 can reach their preferred values. In this embodiment, for example, the reference current 150 is then biased via the mirror 190 resulting in a plurality of target currents 151 serving to supply current for multiple external modules.

By means of the speedup circuit according to this embodiment, the input and parasitic capacitance 125 of the current mirror bank 190 will be charged in a very fast way and the target currents 151 will achieve their desired value quicker. A person skilled in the art will appreciate that other arrangements 190 could profit from the speedup circuit 101.

Generally, each circuitry having a high input capacitance 125 which needs to be charged may provide a better and faster timing behavior by using a speedup circuit 101. A good timing behavior is desired for instance within semiconductor integrated memory circuits which are adapted to operate at very high clock frequencies.

In some embodiments of the speedup circuit the feedback signal causes the circuit to switch off once the capacitance has been charged. Thus, the driver 120 will stop driving the node to which it is connected in response to the operation of the current limiter 110. For instance, if the target currents 151 achieve their nominal value the current limiter 110 could be implemented to command that the driver 120 will be switched off. The nominal values may correspond to desired current values set by an specification or the like.

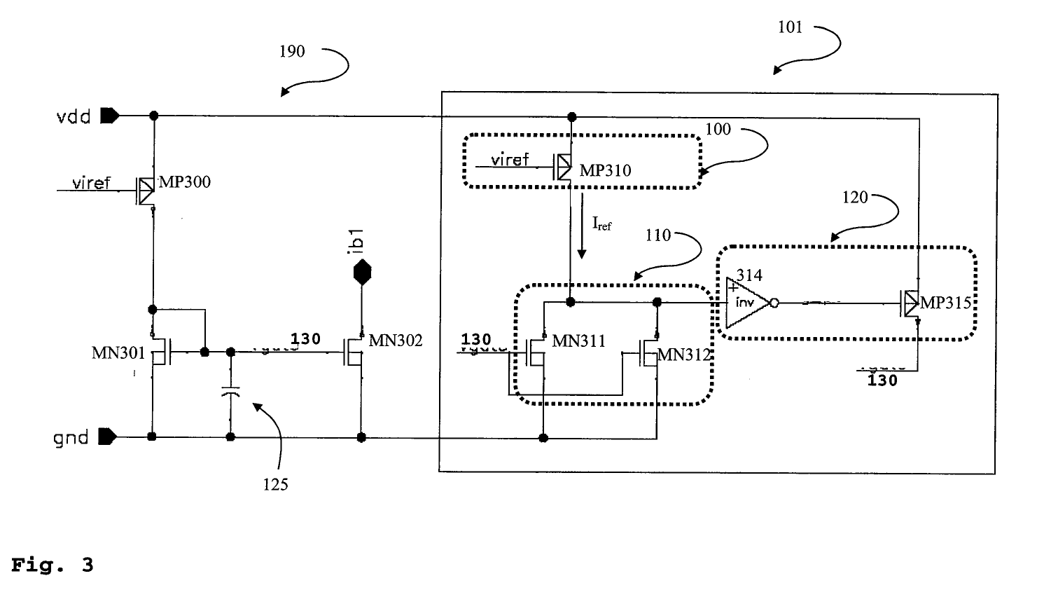

FIG. 3 shows one embodiment of the speedup circuit which is connected to a current mirror bank. Current mirror circuit 191 is shown as a schematic including the parasitic capacitance 125 formed by the gate source capacitors of the transistor MN302. At the node 130, an input capacitance 125 having a value of ca. 500 pF is registered, and this capacitor 125 must be charged for achieving the desired value for the bias current ib1. This charging procedure must be performed within defined timing constraints set by specifications or data sheets. In the practice current mirror 190 includes a plurality of mirrored currents 151 corresponding to output signals of the mirror 190. With reference to FIG. 3, only one leg of the current mirror is shown.

It should be noted that p-channel transistors are referred to symbol MP before the reference number and accordingly n-channel transistors are referred to symbol MN. A person skilled in the art will appreciate that other transistor types can be used to achieve the above mentioned functionality.

The transistor MP300 of the current mirror serves as a reference current source and it generates the desired reference current which can be set by means of viref. This voltage controls the gate source voltage of transistor MP300. MN301 is coupled as a diode and it is as well as MN302 a n-type transistor. The control voltage (gate source voltage) of MN302 is equal to the control voltage of MN301, which means that the currents flowing to MN301 and MN302 are identical. This operation conditions are achieved after the input capacitor 125 is fully charged and MN302 has achieved it operational point. This charging procedure has to be supported by the speedup circuit according to one embodiment. Thus, the critical node, referred to as 130, is connected to the speedup circuit 101 and the node receives an additional supporting current or voltage.

Back to the speedup circuit 101, it should be noted that the node 130 could also be the critical node of a band gap circuitry or the like.

According to this embodiment the control current source includes only one transistor MP310 which is controlled with respect to the reference current on the current mirror 190 side. The reference current and the control current could be set according to a predetermined relationship. FIG. 3 describes an embodiment where the reference current and the control current through MP310 are identical. Nevertheless, other implementations are feasible like, for instance, using more then one transistor instead of MP310. However, even varying the length and width of MP310 is conceivable. An advantage of this embodiment is the defined relationship between the reference current of the circuit to be supported and the control signal or current, respectively of the speedup circuit. This embodiment describes the speedup circuit as a supporting arrangement adapted to support charging of node 130. However, achieving of the target current ib1, 151 by means of the speedup circuit is ensured in a fast manner.

The gate of MP310 is connected with the gate of MP300 which means that both the reference current of the current mirror and the control current of the speedup circuit are simultaneously switched on. In this embodiment both transistors MP300 and MP310 are identical which means that the operating currents through the transistors are equal.

Consequently, the control current of the speedup circuit will flow in turn into the current limiter 110. The current limiter includes two transistors MN311 and MN312. According to one embodiment both transistor are identical. The control input of the current limiter 110 corresponds to the gate connection of both MN311 and MN312. That is, the currents which will flow through MN311 and MN312 have to be equal. MP310 and MP300 have identical control voltages, namely vref, and therefore the same current will flow trough the corresponding transistors. The node formed by the drain legs of the transistors MN311 and MN312 of the current limiter will receive the current flowing through MP310.

According to this embodiment the transistors MN311, MN312 and MN302 are equally dimensioned and integrated. That is during the DC operation point the currents through the corresponding transistors are identical. Accordingly, the node formed by the drain legs of the transistors MN311 and MN312 is charged until the current through MN311 and MN312 is 50% of the I_{ref}. After the above mentioned operational conditions are reached, the aforementioned node is pulled down to the ground, which means that the input of the inverter 314 is 0 (low). Inverter 314 inverts the input which means that the gate of the p-type transistor MP315 becomes high. Accordingly MP315 is switched off. That is, the node 130 of the speedup circuit is switched off and the current mirror will work properly.

According to one embodiment, the geometrical dimensions and the number of transistors used to implement the current limiter affects the switch-off of the whole speedup circuit. In this embodiment the switch-off occurs when the biased current is 50% of the reference current I_{ref}.

Furthermore, in one embodiment, transistor MP310 may not be identically realized with reference to transistor MP300 of the current mirror circuitry.

Furthermore, it is also feasible to replace the inverter 314 with a Schmitt-trigger or the like. By using the Schmitt-trigger a stable operation may be achieved because of the characteristics of the trigger.

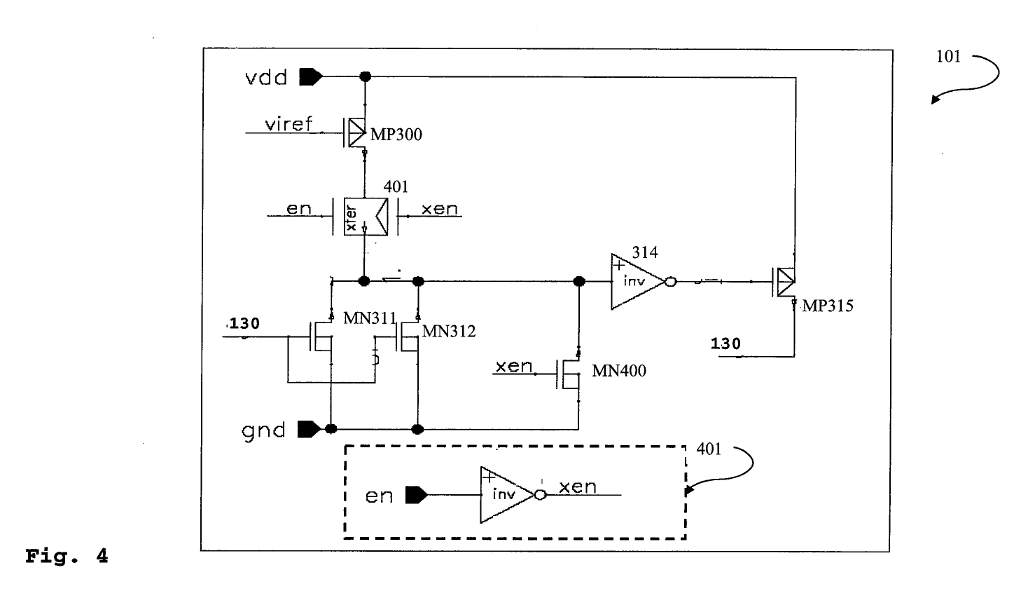

FIG. 4 shows one embodiment of the present invention according to a low power implementation. This embodiment comprises all elements described with reference to FIG. 3 and additionally two control elements MN400 and the switch 401. The switch 401 may be realized as a transfer gate comprising two complementary transistors. The control signals of the transfer gate 401 are graphically described with reference to module 401. The enabling signal en corresponds to the inverted disabling signal xen.

According to this low power embodiment the speedup circuit and further the control part of the circuit, MP301, can be switched off. In other words, power could be saved.

Even though the invention is described above with reference to embodiments according to the accompanying drawings, it is clear that the invention is not restricted thereto but it can be modified in several ways within the scope of the appended claims.

What is claimed is:

1. An apparatus, comprising:
a current source providing an output signal determined by a reference signal;
a driver providing a drive signal related to said reference signal and a feedback signal; and
a current limiter receiving said feedback signal to control said driver.

2. The apparatus according to claim 1, wherein said current source generates a control current.

3. The apparatus according to claim 1, wherein said control current source generates said control current according to a predetermined ratio with respect to said reference signal.

4. The apparatus according to claim 1, wherein said current limiter causes that said driver operates in a predetermined manner.

5. The apparatus according to claim 1, wherein said feedback signal controls the operation of said current limiter.

6. A method for speeding up achieving a target signal related to a reference signal, comprising the steps of:
generating a control current on the basis of said reference signal;
driving an achieving of said target signal; and
limiting said control current on the basis of said driving step.

7. The method according to claim 6, further comprising:
generating said control current according to a predetermined ratio with respect to said reference current.

8. The method according to claim 6, further comprising:
controlling said limiting on the basis of said control current.

9. The method according to claim 8, further comprising:
controlling said limiting on the basis of said ratio.

10. The method according to claim 8, further comprising:
controlling said limiting according to a feedback signal.

11. An apparatus for achieving a target signal related to a reference signal, comprising:
means for generating a control current adjusted according to information related to said reference signal;
means for driving an achieving of said target signal; and
means for limiting a current receiving a feedback signal from said means for driving.

12. The apparatus according to claim 11, wherein said means for generating generates said control current according to a predetermined ratio with respect to said reference signal.

13. The apparatus according to claim 11, wherein said means for limiting causes that said means for driving operates in a predetermined manner.

14. The apparatus according to claim 11, wherein said feedback signal controls the operation of said means for limiting.

15. The apparatus according to claim 11, wherein said circuit is an integrated semiconductor circuit.

16. A system comprising a current mirror bank and a speedup circuit, said speedup circuit comprising:
a current source;
a circuit to provide a drive signal; and
a current limiter;
wherein said speedup circuit is used to support charging of an input capacitance of said current mirror bank.

17. A system according to claim 16, wherein said speedup circuit is operable according to a reference signal of said current mirror bank.

18. A system according to claim 16, wherein said speedup circuit is configurable according to a target signal, said signal being an output signal of said current mirror bank.

19. A system according to claim 16, wherein said current source generates a control current according to a predetermined ratio with respect to said reference signal.

20. A system according to claim 16, wherein said current limiter causes that said circuit operates in a predetermined manner.
